(19) United States
(12) Patent Application Publication
(10) Pub. No.: US 2016/0172630 A1
(43) Pub. Date: Jun. 16, 2016

(54) Optoelectronic Component and Method for Producing an Optoelectronic Component

(71) Applicant: OSRAM OLED GMBH, Regensburg (DE)

(72) Inventors: Thilo Reusch, Donaustauf (DE); Daniel Steffen Setz, Böblingen (DE); Günter Schmid, Hemhofen (DE); Nina Riegel, Tegernheim (DE); Thomas Dobbertin, Regensburg (DE)

(73) Assignee: OSRAM OLED GmbH, Regensburg (DE)

(21) Appl. No.: 14/907,793

(22) PCT Filed: Aug. 5, 2014
(86) PCT No.: PCT/EP2014/066838

§ 371 Date: Jan. 26, 2016

(30) Foreign Application Priority Data
Aug. 7, 2013 (DE) 10 2013 013 129.4

(51) Int. Cl. H01L 51/52; H01L 51/00; H01L 51/56

(52) U.S. Cl. CPC H01L 51/5268; H01L 51/5275; H01L 51/56; H01L 51/0043; H01L 51/0034

(57) ABSTRACT

An optoelectronic component includes an organic functional layer, having an active region that emits electromagnetic radiation, and a outcoupling element disposed in the beam path of the electromagnetic radiation emitted. The outcoupling element includes a matrix material and a separated phase disposed therein or a multitude of separated phases different than the matrix material. The refractive index of the separated phase is less than the refractive index of the matrix material. The separated phase in the matrix material causes scattering of the electromagnetic radiation is generated in the outcoupling element.

This patent application is a national phase filing under section 371 of PCT/EP2014/066838, filed Aug. 5, 2014, which claims the priority of German patent application 10 2013 013 129.4, filed Aug. 7, 2013, each of which is incorporated herein by reference in its entirety.

### TECHNICAL FIELD

The present invention relates to an optoelectronic component and to a process for producing an optoelectronic component.

### BACKGROUND

In optoelectronic components, especially organic light-emitting diodes (OLEDs), only a portion of the light generated is outcoupled directly. The following loss channels may be observed: waveguide effects of the transparent substrate disposed in the beam path of the emitted radiation, waveguide effects in the organic layers and the transparent electrode disposed in the beam path of the emitted radiation, absorption losses owing to materials through which the emitted radiation passes, and the formation of surface plasmons, especially at a metallic electrode, for example, the cathode.

The light conducted into the loss channels cannot be outcoupled from an OLED, more particularly not without additional technical measures.

Methods of increasing the outcoupling of light and hence the light output emitted have to date involved using, for example, on the outside of the substrate, films having scattering particles and films having surface structures, for instance microlenses. Another known method is to provide for direct structuring of the outside of the substrate or to introduce scattering particles into the substrate, for example, glass. Some of these approaches, for example, use of scattering films, are already being used commercially and can be upscaled in terms of the emission area, especially in the case of OLEDs executed as lighting modules. However, these approaches to light outcoupling have the significant disadvantages that the outcoupling efficiency is limited to about 60%-70% of the light conducted within the substrate, and that the appearance of the OLED is significantly affected, since the layers or films applied create a milky, diffusely reflecting surface.

There are also known approaches for outcoupling the light conducted within organic layers or a transparent electrode. However, these approaches have not yet become commercially established in OLED products. For example, the publication Y. Sun, S. R. Forrest, Nature Photonics 2, 483 (2008) proposes the formation of so-called “low-index grids”, wherein structured regions comprising a material having a low refractive index are applied to a transparent electrode. Additionally known is the application of highly refractive scattering regions beneath a transparent electrode in a polymeric matrix material, as described, for example, in publication US 2007/0257608. In this case, the polymeric matrix material generally has a refractive index in the region of n=1.5 and is applied by wet-chemical means.

However, it is not possible with such measures to affect or even outcouple the proportion of light produced in the active region of an OLED which is converted to plasmons.

### SUMMARY

Embodiments of the invention specify an optoelectronic component and a process for producing an optoelectronic component having improved outcoupling of electromagnetic radiation and efficiency.

An optoelectronic component in one embodiment comprises at least one organic functional layer having an active region which emits electromagnetic radiation, an outcoupling element disposed in the beam path of the emitting electromagnetic radiation, wherein the outcoupling element comprises a matrix material and at least one separated phase disposed therein or a multitude of separated phases different than the matrix material. The refractive index of this separated phase is less than the refractive index of the matrix material. The separated phase in the matrix material causes scattering of the electromagnetic radiation in the outcoupling element.

The inventors have found that an outcoupling element which comprises a matrix material and at least one separated phase, in an optoelectronic component, has distinctly increased outcoupling of light, improved efficiency and improved scatter of electromagnetic radiation compared to a conventional outcoupling element of a conventional optoelectronic component. In addition, an outcoupling element in an optoelectronic component comprising a matrix material and at least one separated phase has lower roughness than a conventional outcoupling element which uses, for example, scattering particles (SiO₂) only for outcoupling of light.

Electromagnetic radiation here and hereinafter preferably encompasses electromagnetic radiation having one or more wavelengths or wavelength ranges from an ultraviolet to infrared spectral region; more preferably, the electromagnetic radiation is visible light having wavelengths or wavelength ranges from a visible spectral range between about 350 nm and about 800 nm. Here and hereinafter, electromagnetic radiation may be referred to as “light” or “visible light”.

In the context of this application, the term “component” is understood to mean not just finished components, for example, organic light-emitting diodes (OLEDs) but also substrates and/or organic layer sequences. A composite of an organic layer sequence having a first electrode and a second electrode may, for example, already constitute a component and form part of an overall second component in which, for example, electrical connections are additionally present.

In at least one embodiment, an optoelectronic component has the following elements a substrate on which the outcoupling element has been applied, the substrate being translucent, a first electrode above the outcoupling element, the electrode being translucent, and a layer structure composed of at least one organic functional layer and/or further functional layers above the first electrode.

More particularly, the outcoupling element may be suitable and intended for what is called internal outcoupling, i.e., for reducing that portion of the radiative power generated in the light-emitting layer or of the light generated therein which is conducted in organic functional layers and/or in the translucent electrode.

“Translucent” refers here and hereinafter to a layer which is translucent to visible light. In this case, the translucent layer may be transparent, i.e., clearly transparent, or may at least partially scatter light and/or partly absorb light, such that the translucent layer may also, for example, have a diffuse or milky appearance. More preferably, a layer referred to here as translucent has maximum transparency, such that the absorption of light in particular is as low as possible.

In the context of the present invention, a first layer disposed or applied “on” or “above” a second layer may mean that the first layer is disposed or applied directly on the second layer in direct mechanical and/or electrical contact. In addition, this may also refer to an indirect contact in which further layers are disposed between the first layer and the second layer.

An optoelectronic component in a further embodiment has the following elements a substrate, a first electrode applied above the substrate, a layer structure composed of at least one organic functional layer and/or further functional layers, applied above the first electrode, and a second electrode applied above the layer structure, the electrode being translucent and having an outcoupling element applied thereto.

In a further embodiment, a layer structure composed of at least one organic functional layer and/or further functional layers may comprise the outcoupling element. More particularly, the outcoupling element takes the form of a layer. The outcoupling element has light-scattering and electrically conducting properties as part of the layer structure.

“Separated phase” here and hereinafter is understood to mean a delimited spatial region in which the defining physical and/or chemical parameters are homogeneous. The physical parameters include, in particular, density, refractive index and/or state of matter. The separated phase has at least one interface to the matrix material of the outcoupling element. The separated phase and matrix material differ in terms of at least one chemical and/or physical parameter, such that there is an abrupt change in at least one chemical and/or physical parameter at the interface of the separated phase and the matrix material. For example, the refractive index can increase and/or decrease at the transition of the separated phase and the matrix material. A separated phase distributed within the matrix material of the outcoupling element is a scattering site for the electromagnetic radiation. Particles such as SiO₂, TiO₂, ZrO₂ and/or Al₂O₃, for example, and other particles, for example, inorganic nanoparticles, in the context of the invention, are not in themselves considered to be a separated phase. Particles may be present as filler in the matrix material and in the separated phase.

The refractive index n of a medium, in this connection, gives as a physically dimensionless parameter the factor by which the wavelength and the phase speed of the light in this medium is less than in a vacuum. The value of the refractive index is typically reported for the wavelength of the sodium D line at 589 nm. “Medium” refers here, for example, to the matrix material or the separated phase in the outcoupling element. An organic functional layer in the form of a layer may also be referred to as medium.

In one embodiment, the refractive index of the outcoupling element is greater than or equal to 1.65.

In one embodiment, the refractive index of the matrix material is greater than or equal to 1.65.

In one embodiment, the refractive index of the separated phase is less than 1.65.

The refractive index may increase abruptly at the transition from the separated phase (n less than 1.65) and the matrix material (n greater than 1.65). Differences in refractive index at the interface between separated phase and matrix material result in scattering of the electromagnetic radiation emitted by at least one organic functional layer having an active region.

“Scatter” of the electromagnetic radiation in this connection is understood to mean the deflection of the electromagnetic radiation at the phase boundaries of the separated phase in the matrix material.

The low roughness of the separated phase leads to improved compatibility of the overall outcoupling element with other organic functional layers, the substrate and the first and/or second electrode. In addition, the outcoupling element improves the improved outcoupling of light and efficiency of the optoelectronic component.

In a further embodiment, the outcoupling element, compared to conventional outcoupling elements, has low or zero absorption for the electromagnetic radiation to be outcoupled.

In one embodiment, the separated phase is gaseous and/or liquid.

In one embodiment, a first compound is enriched in the separated phase and is selected from a group comprising N₂, CO₂, CO, NO_{N}, NH₃, water, polar compounds and apolar compounds. NO_{N} here is a collective term for the gaseous oxides of nitrogen, since there are several nitrogen-oxygen compounds because of the many oxidation states of nitrogen. For instance, nitrogen oxides NO_{N} may be N₂O (dinitrogen monoxide), NO (nitrogen monoxide), N₂O₃ (dinitrogen trioxide), NO₂ (nitrogen oxide), N₂O₄ (dinitrogen tetroxide) and N₂O₅ (dinitrogen pentoxide). The first compound may be liquid and/or gaseous. More particularly, the refractive index of the separated phase in that case is less than 1.001; for example, the refractive index of nitrogen (N₂) is 1.000300 and that of carbon dioxide (CO₂) 1.000450. The refractive index of water is 1.33.

The outcoupling element in an optoelectronic component, for example, an OLED, in one embodiment, comprises a matrix material in the solid state of matter and at least one separated phase in the gaseous and/or liquid state of matter. The difference in state of matter between separated phase and matrix material causes scatter of the electromagnetic radiation. This increases the outcoupling of light and efficiency of outcoupling of light from the optoelectronic component.

In one embodiment, the separated phases distributed in the matrix material each have a size between 5 nm and 5 μm, especially between 200 nm and 2 μm.

In a further embodiment, the geometric shape of the separated phases distributed within the matrix material may be as desired. The separated phase may have a geometry that cannot be described exactly or a geometric shape selected from a group comprising spheres, cylinders and ellipses. For example, separated phases in the form of a bubble may be embedded in the matrix material.

In one embodiment, the matrix material is selected from a group comprising monomeric organic compounds, oligomeric organic compounds, polymeric organic compounds and block copolymers.

The outcoupling element may include an organic material, especially a polymer-based material, which may be applied to the substrate, for example, by wet-chemical means. For example, the outcoupling element for this purpose may include one or more of the following materials: polycarbonate (PC), polyethylene naphthalate (PEN), polyethylene terephthalate (PET), polyurethane (PU), polyacrylate, for example, polymethylmethacrylate (PMMA), epoxide, acrylonitrile-butadiene-styrene, polyimide, polybenzoxazoles.

In addition, the matrix material of the outcoupling element may include inorganic nanoparticles. An inorganic nanoparticle may, for example, be a titanate or zirconate in the form of particles, the particle having a size of 1 nm to 1 μm, especially less than or equal to 10 nm. The inorganic nanoparticles and the separated phase in the matrix material have different functions in the outcoupling element. The inorganic nanoparticles in the matrix material may alter, for example, increase and/or reduce, the refractive index of the matrix material. The inorganic nanoparticles do not scatter the electromagnetic radiation. The separated phase in the matrix material scatters the electromagnetic radiation and improves the outcoupling of light and efficiency of the optoelectronic component.

The inventors have found that an outcoupling element in an optoelectronic component comprising a matrix material having a refractive index n within the visible wavelength range and at least one separated phase distributed within the matrix material has improved scatter and outcoupling of the electromagnetic radiation emitted by the component, with only slight absorption of the electromagnetic radiation by the outcoupling element of the invention compared to conventional outcoupling elements. This leads to an improvement in efficiency in the outcoupling of the electromagnetic radiation from the optoelectronic component.

In an outcoupling element according to a further embodiment, the block copolymer may constitute or form either the matrix material or the separated phases.

A block copolymer is a copolymer having blocks joined in a linear manner.

A block is understood to mean a section of a polymer molecule comprising several identical repeat monomer units and at least one constitutional or configurational feature which differs from those of the adjoining blocks.

In one embodiment, a block copolymer has at least two blocks, a first block and a second block, which differ from one another.

More particularly, at least one block in the block copolymer may form at least one separated phase of the outcoupling element distributed within the matrix material.

Distinguishing features of the blocks are, for example, polarity, chemical composition, refractive index, density and/or state of matter. For example, the blocks may differ from one another on the basis of their polarity. For instance, a first block may be hydrophilic, i.e., a block that interacts with polar compounds and does not interact with nonpolar compounds. For example, the first block may comprise or consist of polyethylene oxide (PEO) or polyelectrolytes such as polyacrylic acid (PAA), polymethacrylic acid (PMA) or polydiallyldimethylammonium chloride (DADMAC). A second block may be hydrophobic, i.e., a block that interacts with nonpolar compounds and does not interact with polar compounds. For example, the second block may comprise or consist of polybutadiene (PB), polystyrene (PS), polyethylethylene (PE) or polypropylene oxide (PPO). It should be noted here that the interaction between polar units (dipole-dipole interaction) is much stronger than the interaction between nonpolar units (at least van der Waals interaction). The separation of the phases is driven especially by the strong interactions between polar units; the nonpolar units are effectively displaced from the network of polar units that forms. “Interaction” in this connection means that a block of at least one nonpolar or polar compound forms a chemical bond, intermolecular forces and/or intramolecular forces. Alternatively, it is also possible for the first block to be hydrophobic and the second block hydrophilic. The blocks are joined to one another directly or by constitutional units b that are not part of the blocks.

A block copolymer in a solvent leads to self-aggregation. The solvent may be selective. “Selective” means here that the solvent is a good solvent only for one block. The other block is dissolved to a significantly poorer degree, if at all, in the solvent, i.e., at least three orders of magnitude more poorly than the first block. More particularly, the other block is not dissolved in the solvent. This leads to phase separation of the first and second blocks, with separation of the first block from the second block and/or vice versa. A mesophase may be formed. These details are not restricted to a block copolymer having two blocks. In addition, a third, fourth, fifth, sixth, etc. block may be present in the block copolymer, which differs in terms of a physical and/or chemical property, for example, the polarity, from an adjoining block or z adjoining blocks.

In one embodiment, at least one copolymer comprises at least one first block, the first block having at least one thermally labile group of a first monomer unit. “First monomer unit” refers here and hereinafter to individual or multiple monomers that form the block copolymer. Rather than monomers, it is also possible for oligomers or polymers to form a first monomer unit.

According to the nature, structure and number of the blocks in the block copolymer, a distinction is made between different block copolymers such as diblock copolymer, triblock copolymer, up to multiblock copolymer. Block copolymers have chemically different blocks bonded to one another by covalent bonds.

In one embodiment, individual or multiple monomers that form the block copolymer may have a thermally labile group. Alternatively or additionally, at least one block may have a thermally labile group.

In one embodiment, at least one separated phase in the matrix material is producible from the thermally labile group of the first monomer unit.

In one embodiment, the block copolymer comprises at least one second block, the second block having at least one reactive crosslinkable group of a second monomer unit. “Second monomer unit” refers here and hereinafter to individual or multiple monomers which form the block copolymer. Rather than monomers, it is also possible for oligomers or polymers to form a second monomer unit. More particularly, the second monomer unit is selected from a group comprising polyimide, polybenzoxazole, polyether ether ketone and polysulfone.

In one embodiment, the block copolymer in the form of a matrix material may have at least one reactive crosslinkable group prior to formation of the separated phase.

In one embodiment, the block copolymer has a first block comprising thermally labile groups of the first monomer unit, and a second block comprising reactive crosslinkable groups of the second monomer unit. According to the ratio of the first and second blocks to one another and/or the number of first monomer units in the first block and/or the number of second monomer units in the second block, it is possible to adjust the size of at least one separated phase or of a multitude of separated phases.

In one embodiment, it is possible to produce at least crosslinking of the matrix material from the reactive crosslinkable group of the second monomer unit. In this way, it is possible to produce a more stable outcoupling element, the separated phase of the outcoupling element being stabilized by crosslinking of the matrix material. Crosslinkable groups used may, for example, be oxetanes, acrylates and epoxides. A higher level of crosslinking can achieve an increase in the glass transition temperature. In this way, it is possible to achieve an increase in the thermal stability of the outcoupling element.

In one embodiment, a first and/or second monomer unit of a block copolymer may be selected from a group comprising N,N′-bis(naphthalen-1-yl)-N,N′-bis(phenyl)-9,9-dimethylfluorene, N,N′-bis(3-methylphenyl)-N,N′-bis(phenyl)-9,9-diphenylfluorene, N,N′-bis(naphthalen-1-yl)-N,N′-bis(phenyl)-9,9-diphenylfluorene, N,N′-bis-(naphthalen-1-yl)-N,N′-bis(phenyl)-2,2-dimethylbenzidine, N,N′-bis(3-methylphenyl)-N,N′-bis(phenyl)-9,9-spirobifluorene, 2,2′,7,7′-tetrakis-(N,N-diphenylamino)-9,9′-spirobifluorene, N,N′-bis-(naphthalen-1-yl)-N,N′-bis(phenyl)benzidine, N,N′-bis-(naphthalen-2-yl)-N,N′-bis(phenyl)benzidine, N,N′-bis-(3-methylphenyl)-N,N′-bis(phenyl)benzidine, N,N′-bis(3-methylphenyl)-N,N′-bis(phenyl)-9,9-dimethylfluorene, N,N′-bis(naphthalen-1-yl)-N,N′-bis(phenyl)-9,9-spiro-bifluorene, di[4-(N,N-ditolylamino)phenyl]cyclohexane, 2,2′,7,7′-tetra(N,N-ditolyl)aminospirobifluorene, 9,9-bis[4-(N,N-bis(biphenyl-4-yl)amino)phenyl]-9H-fluorene, 2,2′,7,7′-tetrakis[N-naphthalenyl(phenyl)amino]-9,9-spirobifluorene, 2,7-bis[N,N-bis(9,9-spirobifluoren-2-yl)amino]-9,9-spirobifluorene, 2,2′-bis[N,N-bis-(biphenyl-4-yl)amino]-9,9-spirobifluorene, N,N′-bis-(phenanthren-9-yl)-N,N′-bis(phenyl)benzidine, N,N,N′,N′-tetranaphthalen-2-ylbenzidine, 2,2′-bis(N,N-diphenylamino)-9,9-spirobifluorene, 9,9-bis[4-(N,N-bis(naphthalen-2-yl)amino)phenyl]-9H-fluorene, 9,9-bis[4-(N,N′-bis(naphthalen-2-yl)-N,N′-bisphenylamino)-phenyl]-9H-fluorene, titanium oxide phthalocyanine, copper phthalocyanine, 2,3,5,6-tetrafluoro-7,7,8,8-tetracyanoquinodimethane, 4,4′,4″-tris(N-3-methyl-phenyl-N-phenylamino)triphenylamine, 4,4,4″-tris(N-(2-naphthyl)-N-phenylamino)triphenylamine, 4,4′,4″-tris-(N-(1-naphthyl)-N-phenylamino)triphenylamine, 4,4′,4″-tris(N,N-diphenylamino)triphenylamine, pyrazino[2,3-f][1,10]phenanthroline-2,3-dicarbonitrile, N,N,N′,N′-tetrakis(4-methoxyphenyl)benzidine, 2,7-bis-[N,N-bis(4-methoxyphenyl)amino]-9,9-spirobifluorene, 2,2′-bis[N,N-bis(4-methoxyphenyl)amino-9,9-spirobi-fluorene, N,N′-di(naphthalen-2-yl)-N,N′-diphenyl-benzene-1,4-diamine, N,N′-diphenyl-N,N′-di[4-(N,N-ditolylamino)phenyl]benzidine and N,N′-diphenyl-N,N′-di-[4-(N,N-diphenylamino)phenyl]benzidine.

More particularly, the first and/or second monomer unit may be polymerized to give a copolymer, for example, block copolymer. The copolymer may have charge-conducting properties, for example, hole-conducting and/or electron-conducting properties. This gives rise to a double function for the outcoupling element comprising the block copolymer as matrix material, firstly light scattering and light outcoupling and secondly charge conductivity. This has the advantage that it is necessary to use only one matrix material to achieve different functions. This saves material and costs.

In one embodiment, the outcoupling element takes the form of a layer. The thickness of the layer is 100 nm to 100 μm, preferably 4 μm to 40 μm, for example, 20 μm.

In a further embodiment, the translucent electrode is configured as an anode and can thus serve as hole-injecting material. In that case, the other electrode is configured as a cathode. Alternatively, the translucent electrode can also be configured as a cathode and hence serve as electron-injecting material. In that case, the other electrode is configured as an anode.

The translucent electrode which may take the form of the first or second electrode may, for example, include a transparent conductive oxide or consist of a transparent conductive oxide. Transparent conductive oxide (“TCOs” for short) are transparent conductive materials, generally metal oxides, for example, zinc oxide, tin oxide, cadmium oxide, titanium oxide, indium oxide or indium tin oxide (ITO). As well as binary metal-oxygen compounds, for example, ZnO, SnO₂ or In₂O₃, the group of the TCOs also includes ternary metal-oxygen compounds, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides. Moreover, the TCOs do not necessarily correspond to a stoichiometric composition and may also be p- or n-doped. Further possible materials for the transparent electrode may be selected from networks composed of metallic nanowires, for example, of Ag, which may be combined with conductive polymers, networks composed of carbon nanotubes which may be combined with conductive polymers, and of graphene layers and composites.

In a further preferred embodiment, the translucent electrode includes or consists of ITO. More particularly, the translucent electrode may have a thickness of not less than 50 nm and not more than 200 nm. Within such a thickness range, transmission within the visible spectral range of the translucent electrode is not less than 80% and the specific resistivity p is within a range from about 150 to 500 μΩ·cm.

In a further embodiment, the first and/or second electrode includes a metal selected from aluminum, barium, indium, silver, gold, magnesium, calcium and lithium, and compounds, combinations and alloys. More particularly, the first and/or second electrode may include Ag, Al or alloys therewith, for example, Ag:Mg, Ag:Ca or Mg:Al. Alternatively or additionally, the first and/or second electrode may also include one of the abovementioned TCO materials.

In a further embodiment, the optoelectronic component has a hole-conducting layer, for example a hole injection layer, a hole transport layer or a combination thereof.

In a further embodiment, the optoelectronic component has an electron-conducting layer, for example, an electron injection layer, an electron transport layer or a combination thereof.

In a further embodiment, one or more charge carrier-conducting layers, i.e., electron- and/or hole-conducting layers, include a dopant. The dopant advantageously brings about an increase in conductivity, in order to keep the operating voltage of the organic light-emitting component low.

The dopant used may, for example, be a metal oxide, an organometallic compound, an organic material or a mixture thereof, for example, WO₃, MoO₃, V₂O₅, Re₂O₇ and Re₂O₅, dirhodium tetra(trifluoroacetate) (Rh₂(TFA)₄) or the isoelectronic ruthenium compound Ru₂(TFA)₂(CO)₂ or an organic material which has aromatic functional groups or is an aromatic organic material, for example, aromatic materials having fluorine and/or cyanide (CN) substituents.

Above the electrodes and the organic functional layers may additionally be disposed an encapsulation arrangement. The encapsulation arrangement may be executed, for example, in the form of a glass cover or, preferably, in the form of a thin-layer encapsulation.

An encapsulation arrangement in the form of a thin-film encapsulation is understood in the present context to mean a device suitable for forming a barrier with respect to atmospheric substances, especially with respect to moisture and oxygen and/or with respect to further damaging substances, for instance corrosive gases, for example, hydrogen sulfide. For this purpose, the encapsulation arrangement may have one or more layers each having a thickness of not more than a few hundred nanometers.

Alternatively or additionally, the encapsulation arrangement may have at least one or a multitude of further layer(s), i.e., especially barrier layers and/or passivation layers. In one embodiment, a thin-film encapsulation may also be incorporated between the translucent electrode and outcoupling structure, provided that the effective refractive index of the thin-film encapsulation is not less than the refractive index of the outcoupling structure. The advantage of such an arrangement is the protection of the OLED from harmful substances which could enter the organic layer stack from the outcoupling structure.

Additionally specified is a process for producing an optoelectronic component, comprising the following process steps: A) providing a substrate, B) applying the outcoupling element above the substrate, C) producing a layer structure composed of at least one organic functional layer and/or further functional layers, wherein the outcoupling element is formed above the substrate as one of the layers of this layer structure and/or as a layer that does not form part of this layer structure, and wherein, after process step B), at least one separated phase is formed in the matrix material of the outcoupling element.

The same definitions and embodiments as specified above in the description for the optoelectronic component apply to the process for producing an optoelectronic component. This applies especially to the layer structure, the outcoupling element, the organic functional layer and further functional layers, the substrate, the separated phase and the matrix material.

In one embodiment, before or after process step C, a first compound which forms the separated phase is produced.

In one embodiment, the at least one separated phase in the matrix material of the outcoupling element is produced by thermal treatment, by treatment with electromagnetic radiation and/or by addition of an initiator material. Treatment with electromagnetic radiation can be effected by means of radiation from the ultraviolet range of electromagnetic radiation or electron beams. More particularly, temperatures used for treatment of the matrix material are above 150° C.

In a further embodiment, process step B additionally comprises a process step B′:

mixing a blowing agent into the matrix material, wherein the blowing agent, after application of the outcoupling element, is decomposed thermally and/or by means of radiation and forms a first compound which differs from the matrix material, wherein the first compound forms at least one separated phase in the matrix material, and wherein the blowing agent is selected from a group comprising hydrogencarbonate of the alkali metals, hydrogencarbonate of the alkaline earth metals, sodium hydrogencarbonate (NaHCO₃) and ammonium hydrogencarbonate (NH₄HCO₃).

More particularly, the blowing agent can be decomposed at temperatures around 60° C. Sodium hydrogencarbonate (NaHCO₃) as blowing agent decomposes from 50° C. upward. Ammonium hydrogencarbonate (NH₄HCO₃) as blowing agent decomposes from 60° C. upward. Above a temperature of 50° C., hydrogencarbonate of the alkali metals or alkaline earth metals decomposes. This forms at least gases as reaction products. According to the blowing agent used, reaction products formed include water and/or gaseous carbon dioxide and/or gaseous ammonia. These gases can be incorporated as the first compound in the separated phase of the matrix material in the outcoupling element. This increases the outcoupling of the electromagnetic radiation from the optoelectronic component.

In one embodiment, the process for producing an optoelectronic component comprises, after process step B, B′ or C, D) crosslinking of the matrix material.

The matrix material polymerized in process step D, with its separated phases, forms a mesh-like structure.

In one embodiment, treatment of the outcoupling element which is in the form of a layer and comprises the matrix material with thermal energy or electromagnetic radiation or by addition of an initiator material can generate a chemical reaction in the matrix material. The chemical reaction produces the separated phase in the matrix material. More particularly, the matrix material can subsequently be polymerized. The polymerized matrix material with its separated phases forms a mesh-like structure. In this way, the separated phase can be stabilized after formation thereof. The outcoupling of light and efficiency are respectively increased and improved by more stable separated phases.

In one embodiment, in process step B, a formulation comprising at least one solvent and matrix material can be utilized. In addition, the formulation may comprise blowing agents or further auxiliaries for film formation or wetting or for adjustment of viscosity. More particularly, the matrix material in the outcoupling element is a block copolymer, as already explained in the description of the optoelectronic component. Suitable solvents are water, polar solvents or apolar solvents. The block copolymer, because of its chemical structure and/or its amphiphilic character, has a tendency to self-aggregation and/or phase separation.

The block copolymer associates spontaneously to form stable, highly ordered, three-dimensional structures owing to weak noncovalent bonds. The stability of the structures is based especially on the large number of noncovalent bonds realized inter- and intramolecularly. For example, at least one block copolymer having a hydrophilic block and a hydrophobic block has at least one mesophase. A mesophase of diblock copolymers having at least one A block and one B block can be configured such that the A block forms cubic body-centered spheres (BCC), hexagonally arranged cylinders or a double gyroid lattice. Lamellae composed of the A and B blocks would also be possible. Alternatively, it is possible that the B block forms cubic body-centered spheres (BCC), hexagonally arranged cylinders or a double gyroid lattice. A gyroid structure is understood to mean a structure having a gyroid surface, that divides the space into two component volumes, usually into a smaller volume (filled by one block) and a larger volume (a block which does not correspond to the block in the smaller component volume). The smaller component volume is formed by a labyrinth of tubes having triple linkage to one another. The linkage points are at point positions in the cubic lattice. The tripods are each tilted by 70.53° with respect to one another and the twisting continues in the manner of a helix in all three spatial directions. The type of mesophase depends on the length, composition and sequence of the individual blocks of the block copolymer, and on process step B.

In one embodiment, the process for producing an optoelectronic component comprises, after process step B, B′, C or D, E) drying at least the substrate, the outcoupling element and/or the layer structure, or F) curing the substrate, the outcoupling element and/or the layer structure.

In one embodiment, process steps E and F can be conducted together or successively.

In a further embodiment, in process step E, the solvent is removed from the outcoupling element. The mesophase of the block copolymer is not affected or altered by removal of the solvent.

In one embodiment, the separated phase can be produced prior to process step E or together with process steps E and F.

In one embodiment, in process step E or F, the matrix material comprising oligomeric and/or monomeric compounds can be polymerized. More particularly, treatment of the matrix material with thermal energy or electromagnetic radiation or by addition of an initiator material and hence the production of at least one separated phase and the polymerization of the matrix material can be effected simultaneously.

In one embodiment, terminal groups of the matrix material decompose chemically and/or terminal groups of the matrix material react chemically with other terminal groups of the matrix material and form at least one separated phase.

More particularly, terminal groups of the matrix material, for example, thermally labile groups of the first monomer unit, decompose chemically at temperatures above 150° C., for example, 180° C.

More particularly, the terminal groups of the matrix material can be brought into closer spatial proximity to one another through formation of the mesophases of the block copolymer compared to conventional compounds which do not form mesophases. The terminal groups of the matrix material react chemically with one another, forming a separated phase comprising the first compound, for example, N₂, CO₂, CO and/or NO_{N}. The chemical reaction proceeds in a spatially inhomogeneous manner, meaning that it cannot proceed at every terminal group of the matrix material in the outcoupling element. The size of the separated phase and the distribution thereof in the matrix material is controllable and adjustable via the molecular form of the matrix material and/or blowing agent and/or via process parameters. Process parameters are especially temperature, viscosity of the matrix material and/or pressure.

In one embodiment, a process temperature, for example, in process step E or F, can be set such that it is above the decomposition temperature of the first block having at least one thermally labile group of a first monomer unit of a block copolymer. In this way, a separated phase can be produced. In terms of process technology, it is advisable to choose the process temperature such that it is between the decomposition temperature and/or glass transition temperature of the first and/or second block. The process temperature is typically above 150° C., for example, 180° C.

### BRIEF DESCRIPTION OF THE DRAWINGS

Further advantages and advantageous embodiments and developments of the subject matter of the invention are to be elucidated in detail hereinafter with reference to figures and working examples.

The figures show:

FIG. 1 a schematic side view of a conventional optoelectronic component;

FIG. 2a a schematic side view of an optoelectronic component according to one embodiment;

FIG. 2b a schematic side view of an optoelectronic component according to one embodiment;

FIG. 2c a schematic side view of an optoelectronic component according to one embodiment;

FIG. 3 a schematic structure of block copolymers;

FIG. 4 a phase separation of block copolymers; and

FIG. 5 mesophases of block copolymers.

In the working examples and figures, identical or equivalent constituents are each given the same reference numerals. The elements shown and other size ratios relative to one another should fundamentally not be regarded as being to scale.

### DETAILED DESCRIPTION OF ILLUSTRATIVE EMBODIMENTS

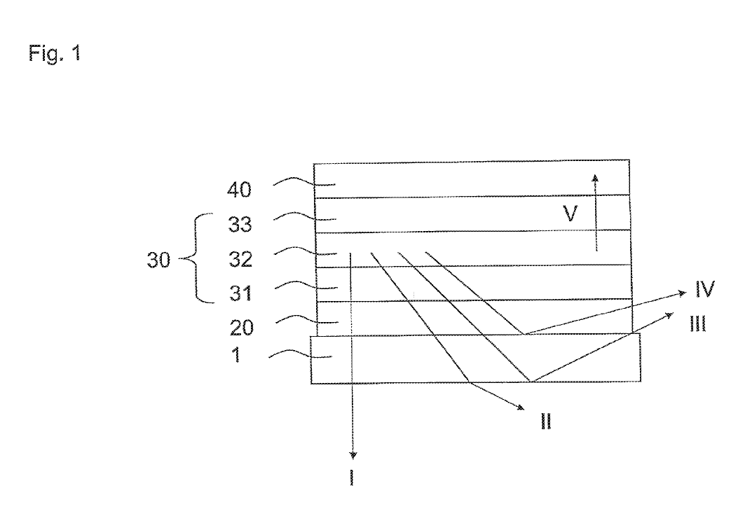

FIG. 1 shows the schematic side view of a conventional optoelectronic component using the example of an OLED. The reference numeral 1 denotes the substrate consisting, for example, of glass. Disposed atop the substrate are a first electrode 20, a layer structure 30 composed of at least one organic functional layer and/or further functional layers, and a second electrode 40. The layer structure 30 composed of at least one organic functional layer and/or further functional layers comprises, for example, a radiation-emitting layer 32, a first charge transport layer 31 and a second charge transport layer 33. Charge carriers may be negatively charged (electrodes) and/or positively charged (holes). It is also possible for further functional layers (not shown here), for example, charge injection layers or charge-blocking layers, to be present in the layer structure 30 composed of at least one organic functional layer and/or further functional layers. The first electrode 20 and/or second electrode 40 may be transparent or translucent. The first electrode 20 and/or second electrode 40 may be a transparent conductive oxide, for example, zinc oxide, tin oxide, cadmium oxide, titanium oxide, indium oxide or indium tin oxide (ITO).

“Transparent” in the context of the present invention means that the material has a transparency of >60% to 100%, preferably greater than 80%, for example, 90%, at least in some regions, but preferably over the entire range, of visible light.

If a voltage is applied (not shown here) between the first electrode 20 and the second electrode 40, current flows through the optoelectronic component. In this case, electrons are injected from the cathode into an electron injection layer, and holes from the anode. The holes and electrons recombine in the radiation-emitting layer 32, forming electron-hole pairs, called excitons, which are capable of emitting electromagnetic radiation.

For the sake of clarity, this figure does not show any encapsulation or an outer layer, but these may be present.

Such an OLED has various loss channels through which light generated in the light-emitting layer 32 is lost to an outside observer. These possible loss channels are illustrated schematically by the arrows I, III, IV and V in FIG. 1.

Waveguide effects of the transparent substrate 1 disposed in the beam path of the emitted light are indicated by the arrow III, waveguide effects in the organic functional layers 30 and the transparent electrode 20 disposed in the beam path of the emitted light are indicated by the arrow IV, absorption losses owing to materials in the organic functional layers 30 or in the substrate 1 are indicated by the arrow I, and the formation of surface plasmons, especially at a metallic electrode, for example, the cathode 40, are indicated by the arrow V.

Optoelectronic components according to embodiments of the invention may especially reduce or prevent the loss channels III and/or IV.

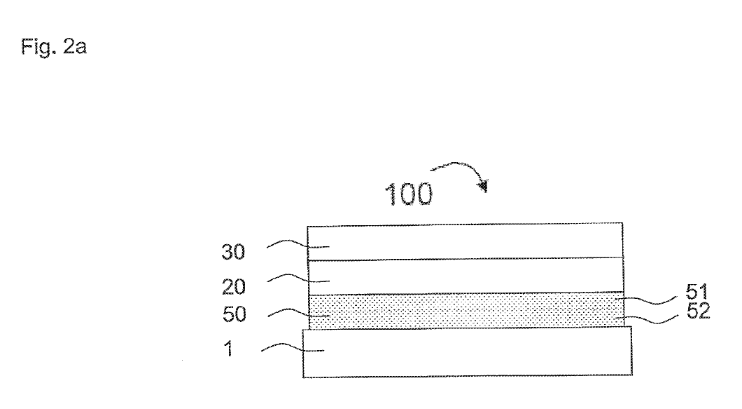

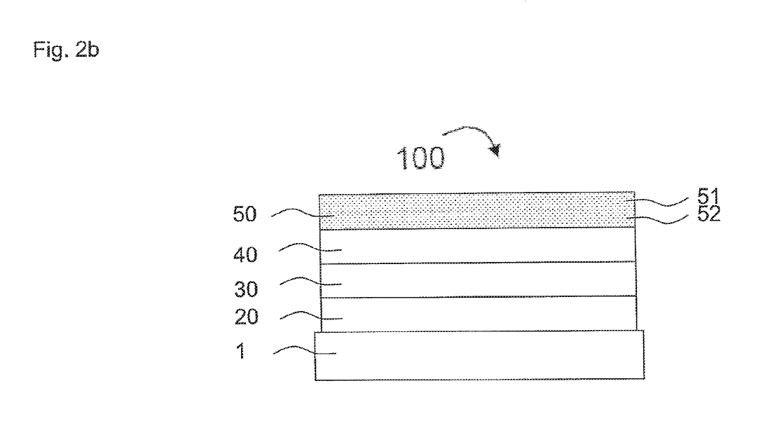

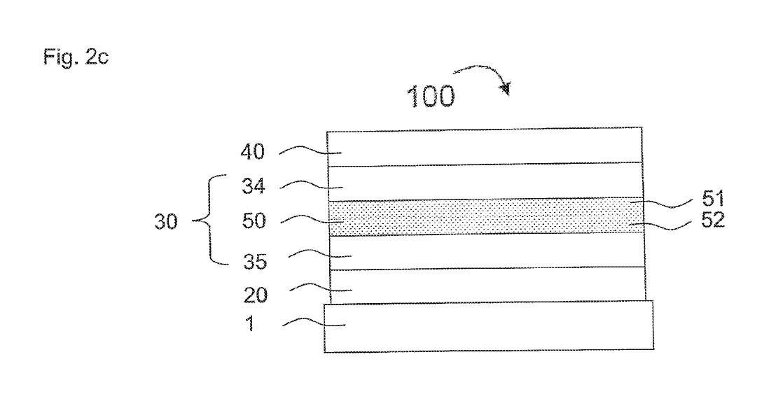

FIG. 2a shows a working example of an optoelectronic component 100. The latter has a substrate 1. Applied to the substrate 1 is an outcoupling element 50, here in the form of a layer. The outcoupling element includes a matrix material having a multitude of separated phases 51, here in the form of spheres. Applied atop the outcoupling element 50 is a first electrode 20 which is translucent. Applied above the translucent first electrode is a layer structure 30 composed of at least one organic functional layer and/or further functional layers.

The optoelectronic component 100 takes the form of a bottom emitter, and for that purpose has a translucent substrate 1 made from glass. Alternatively, the substrate 1 may also include or consist of another translucent material, for example, a plastic or a glass/plastic laminate.

The layer structure 30 has at least one organic functional layer and/or further functional layers. At least one organic functional layer may be a light-emitting layer 32 including organic or organometallic light-emitting material selected, for example, from phosphorescent or fluorescent metal complexes or polymeric materials. Examples of polymeric compounds are derivatives of polyfluorene, polythiophene and polyphenylene; examples of phosphorescent compounds are Ir(ppy)₃ (tris(2-phenylpyridine)iridium(III)), tris(8-hydroxyquinolato)aluminum(III) or Ru(dtb-bpy)₃*2(PF₆) (tris[4,4′-di-tert-butyl-(2,2′)-bipyridine]-ruthenium(III) complex); examples of fluorescent compounds are BCzVBi (4,4′-bis(9-ethyl-3-carbazovinylene)-1,1′-biphenyl) or DPAVBi (4,4-bis[4-(di-p-tolylamino)styryl]biphenyl). The light-emitting layer 32 may further comprise a matrix material with the light-emitting material intercalated therein.

Further possible functional layers in the layer structure 30 which may be present in a component according to FIG. 2a, but are not shown explicitly here for the sake of clarity, include, for example, charge transport layers or charge injection layers.

The outcoupling element 50 includes a matrix material 52 having a multitude of separated phases 51 having a lower refractive index than the matrix material 52. The separated phase may, for example, be air-filled or liquid- and/or gas-filled.

At least one separated phase or a multitude of separated phases may be distributed homogeneously or inhomogeneously in the matrix material of the outcoupling element. In this connection, “homogeneously” means a homogeneous spatial distribution of the separated phases in the matrix material of the outcoupling element. In this connection, “inhomogeneously” means an inhomogeneous spatial distribution of the separated phases in the matrix material of the outcoupling element, so as to form concentration gradients. In one embodiment, at least one separated phase may be spaced apart from another separated phase or a multitude of separated phases. Alternatively or additionally, at least one separated phase may aggregate with at least one other separated phase, such that at least one separated phase together with the other separated phase forms a common interface with the matrix material of the outcoupling element.

In addition, the matrix material may include particles, for example, SiO₂, TiO₂, ZrO₂ and/or Al₂O₃, which are not part of the separated phase. The particles can modify the refractive index of the matrix material. The outcoupling element can have the effect that at least a portion of the light waveguided in the translucent first electrode 20 or in the organic functional layers can be outcoupled from the optoelectronic component 100 through the substrate 1.

Above the electrodes 20, 40 and the organic functional layers may additionally be disposed an encapsulation arrangement, which is not shown for the sake of clarity. The encapsulation arrangement may be executed, for example, in the form of a glass cover or, preferably, in the form of a thin-film encapsulation, as described above in the description. In addition, it may be necessary, especially in the case of an outcoupling element 50 including a polymer, that an encapsulation arrangement in the form of a thin-film encapsulation is formed thereon beneath the translucent first electrode 20.

FIG. 2b shows a working example of an optoelectronic component 100. The latter has a substrate 1. Applied to the substrate 1 is a first electrode 20, here in the form of a layer. Above the first electrode is disposed a layer structure 30 composed of at least one organic functional layer and/or further functional layers and a second electrode 40 which may be translucent. Above the second electrode is disposed the outcoupling element 50.

The optoelectronic component 100 takes the form of a top emitter. Additionally and/or alternatively, the second electrode may also be transparent and/or the second electrode may be executed as the anode and the first electrode as the cathode. In this case, the electromagnetic radiation emitted by an organic functional layer having an active region may be outcoupled via the translucent second electrode and the outcoupling element.

For the optoelectronic component 100 configured as a top emitter, which comprises the outcoupling element, as described in FIG. 2a, it is possible to use the same materials for further constituents of the optoelectronic component 100, such as first electrode, second electrode, organic functional layers, substrate, etc.

The second electrode 40, in the form of the cathode, for example, may include a metal selected from a group comprising silver, aluminum, cadmium, barium, indium, magnesium, calcium, lithium and gold. The cathode may also be in multilayer form. The second electrode 40 may be reflective or transparent. If the second electrode 40 is transparent, it may include the materials mentioned with regard to the transparent first electrode 20.

FIG. 2c shows a working example of an optoelectronic component 100. The latter has a substrate 1. Applied to the substrate 1 is a first electrode 20, here in translucent form and in the form of a layer. Above the first electrode is disposed a layer structure 30 composed of at least one organic functional layer and/or further functional layers, which comprises the outcoupling element 50. Above the layer structure 30 is disposed a second electrode.

The outcoupling element, in addition to its light-scattering properties, has adequate electrical conductivity.

An organic functional layer configured as a hole transport layer may include monomeric molecules, for example, triarylamines or thiophene. The hole transport layer may be disposed above the first electrode comprising ITO. To increase the conductivity, the outcoupling element may additionally comprise electrically conductive materials which are hole- or electron-conducting. In addition, the outcoupling element may be doped.

For the optoelectronic component 100 as configured in FIG. 2c, as described in FIGS. 2a and 2b, it is possible to use the same materials for further constituents of the optoelectronic component 100, such as first electrode, second electrode, organic functional layers, substrate, etc.

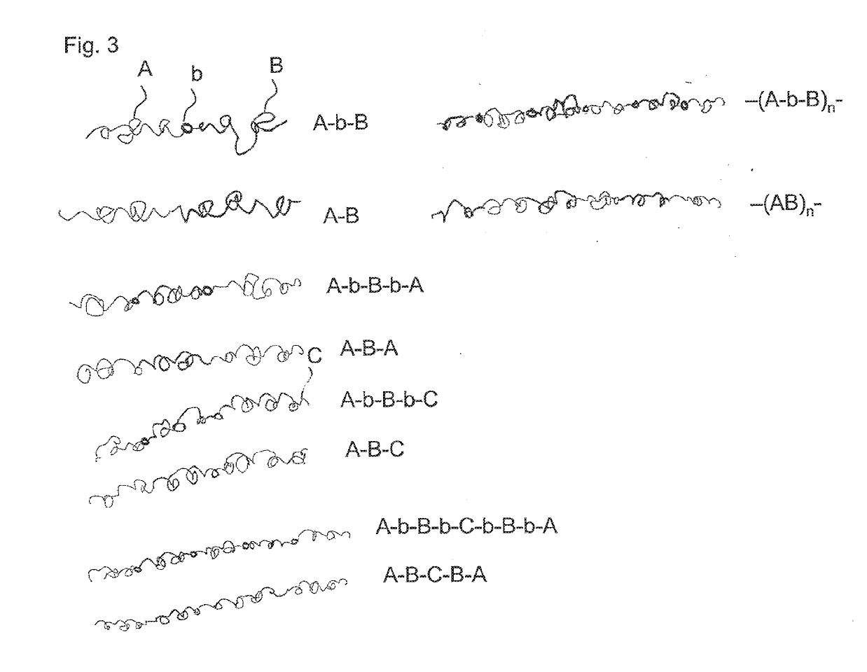

FIG. 3 shows a schematic of block copolymers. The matrix material of the outcoupling element may comprise at least one of these block copolymers, as already detailed in the general part of the description.

Diblock copolymers have an A-b-B or A-B structure, where an A block is joined to a B block directly or via a constitutional unit b. Triblock copolymers have an A-b-B-b-A or A-B-A structure which shows a sequence of an A block with a B block and an A block. Triblocked-copolymers or else triblock copolymers called have an A-b-B-b-C or A-B-C structure having a sequence of an A block with a B block and a C block. Pentablock copolymers have an A-b-B-b-C-b-B-b-A or A-B-C-B-A structure having a sequence of A block, B block, C block, B block and an A block. Multiblock copolymers have the -(AB)ₙ- or -(A-b-B)ₙ- structural unit where the A and B blocks repeat in alternation with a number n in the multiblock copolymer. In all embodiments of the block copolymers, the blocks are joined to one another directly or via a constitutional unit b.

For example, a triblock copolymer has two polyethylene oxide blocks and a polypropylene oxide block between these two blocks and the following structural formula:

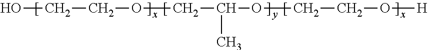

x here denotes the number of monomer units in the particular polyethylene oxide block, and y here denotes the number of monomer units in the polypropylene oxide block.

In one embodiment, the matrix material of the outcoupling element may comprise at least two block copolymers or a multitude of block copolymers. For example, the matrix material may be a mixture of diblock and triblock copolymers. Polymerization of the different block copolymers with one another is likewise possible.

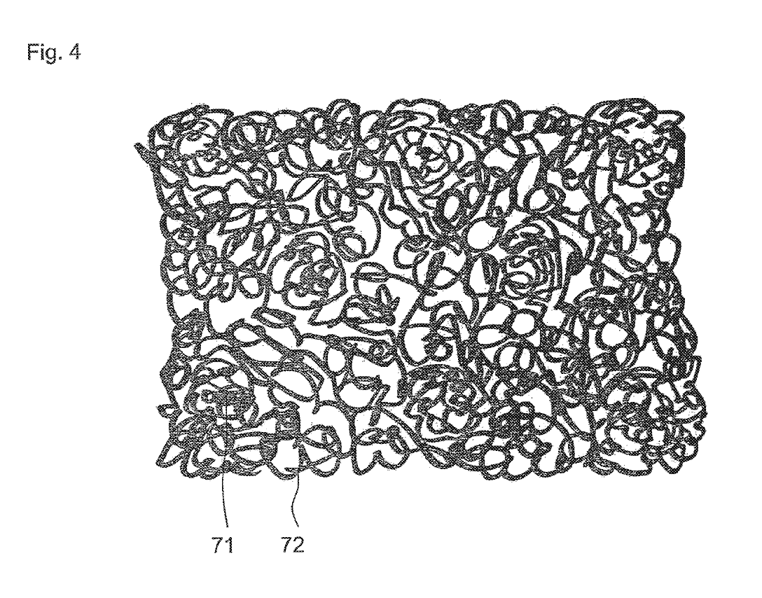

FIG. 4 shows a schematic of the phase separation of a diblock copolymer. The diblock copolymer comprises at least one first block (71) and at least one second block (72) which differ by a physical property, for example, polarity. The first block (71), for example, is hydrophilic and the second block (72) hydrophobic. Because of this bipolar property, the blocks separate into microphases, for example, as a result of addition of a selective solvent, and form periodic nanostructures and/or morphologies and/or mesophases. The nanostructures and/or morphologies and/or mesophases have different physical and/or mechanical properties compared to non-separated block copolymers. More particularly, at least one block copolymer forms a highly ordered square or hexagonal arrangement.

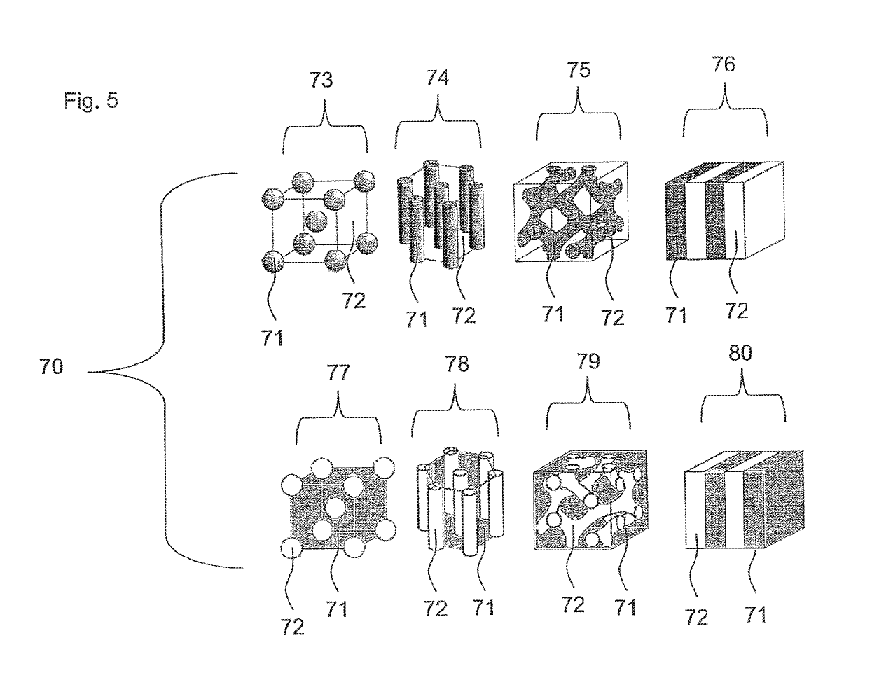

FIG. 5 shows a schematic of possible mesophases of a diblock copolymer having at least one first block (71) which is hydrophilic, for example, and at least one second block (72) which is hydrophobic, for example. Alternatively, the first block may be hydrophobic and the second block hydrophilic. Amphiphilic block copolymers having a hydrophilic block and a hydrophobic block, at low concentration from a particular CMC upward (critical micelle concentration), form micellar structures in a selective solvent (not shown here). Water is the most commonly used solvent. The CMC is in the range from 10⁻⁹ mol/L to 10⁻⁴ mol/L for block copolymers. Preferred mesophases are spherical structures. Cylindrical or worm-shaped micelle structures and vesicles may be formed (not shown here). Block copolymer micelles typically have a diameter of 10-100 nm. If the block copolymer concentration is increased, lyotropic phases may be found, particularly cubic (73, 77), hexagonal (74, 78) and lamellar phases (76, 80). The lamellar phase has double block copolymer layers which may be separated from one another by the solvent. In the hexagonal phase (74, 78), cylindrical micelles are arranged in a two-dimensional hexagonal crystal. The preferred mesophases are the cubic phase (73, 77) in which spherical micelles are arranged in a cubic structure, the hexagonal phase (74, 78) and/or a bicontinuous cubic or gyroid structure (75, 79) in which not only the solvent but also the hydrophobic portions are joined to one another in such a way that the cubic symmetry is still conserved. According to the volume fraction of the first block to the second block, the first block may account for the smaller component volume and the second block for the greater component volume of the block copolymer and vice versa. The volume fraction results in mesophases, by virtue, for example, of the first block accounting for the smaller component volume and the second block for the greater component volume (73, 74, 75, 76). In the reverse case, inverted mesophases are formed, in which the first block accounts for the greater component volume and the second block for the smaller component volume (77, 78, 79, 80).

As a result of the aggregation to give mesophases, the terminal groups of the block copolymer can come into close spatial proximity to one another. This promotes a chemical reaction of the terminal group of the block copolymer, and so at least one separated phase in the matrix material of the outcoupling element can be produced in a preferential and simple manner. The mesophase may additionally have light-scattering properties. This increases light outcoupling and efficiency in the optoelectronic component.

These details are not limited to diblock copolymers. Instead, the details may also be applied to a triblock copolymer, pentablock copolymer, right up to a multiblock copolymer.

The invention is not restricted by the description with regard to the working examples or specified combinations of features; instead, the invention also includes individual new features as such and any combination of features specified, which especially includes any combination of features in the claims, even if this feature or this combination itself is not specified explicitly in the claims or working examples.

1-16. (canceled)

17. An optoelectronic component comprising:
an organic functional layer having an active region that emits electromagnetic radiation;
an outcoupling element disposed in a beam path of the electromagnetic radiation emitted by the active region;
wherein the outcoupling element comprises a matrix material and a separated phase disposed therein;
wherein a refractive index of the separated phase is less than a refractive index of the matrix material; and
wherein the separated phase in the matrix material causes scattering of the electromagnetic radiation in the outcoupling element.

18. The optoelectronic component according to claim 17, wherein the outcoupling element comprises the matrix material and a plurality of separated phases different than the matrix material.

19. The optoelectronic component according to claim 18, wherein the separated phases distributed in the matrix material each have a size between 5 nm and 5 μm.

20. The optoelectronic component according to claim 17, wherein the matrix material comprises a block copolymer, wherein the block copolymer comprises a first block having a thermally labile group of a first monomer unit from which the separated phase can be generated in the matrix material, and wherein the block copolymer comprises a second block, wherein the second block has a reactive crosslinkable group of a second monomer unit.

21. The optoelectronic component according to claim 17, wherein the separated phase is gaseous or liquid.

22. The optoelectronic component according to claim 17, wherein the outcoupling element has a refractive index of greater than or equal to 1.65.

23. The optoelectronic component according to claim 17, wherein a first compound is enriched in the separated phase, the first compound comprising a compound selected from the group consisting of N₂, CO₂, CO, NO_{N}, NH₃, water, polar compounds and apolar compounds.

24. The optoelectronic component according to claim 17, wherein the matrix material comprises a material selected from the group consisting of monomeric organic compounds, oligomeric organic compounds, polymeric organic compounds and block copolymers.

25. The optoelectronic component according to claim 24, wherein a block copolymer comprises a first block having a thermally labile group of a first monomer unit.

26. The optoelectronic component according to claim 25, wherein the thermally labile group of the first monomer unit can be used to produce a separated phase in the matrix material.

27. The optoelectronic component according to claim 24, wherein the block copolymer comprises a second block, wherein the second block has a reactive crosslinkable group of a second monomer unit.

28. A method for producing an optoelectronic component according to claim 17, the method comprising:
providing a substrate;
producing a layer structure composed of a plurality of layers that include an organic functional layer;
applying the outcoupling element above the substrate, wherein the outcoupling element is formed above the substrate as one of the layers of the layer structure or as a layer that does not form part of the layer structure; and
after applying the outcoupling element, forming a separated phase in the matrix material of the outcoupling element.

29. A method for producing an optoelectronic component, the method comprising:
forming a layer structure over a substrate, the layer structure composed of a plurality of layers that include an organic functional layer that has an active region that emits electromagnetic radiation;
applying an outcoupling element above the substrate in a beam path of the electromagnetic radiation emitted by the active region, wherein the outcoupling element is formed as one of the layers of the layer structure or as a layer that does not form part of the layer structure; and
after applying the outcoupling element, forming a separated phase in a matrix material of the outcoupling, wherein a refractive index of the separated phase is less than a refractive index of the matrix material and wherein the separated phase in the matrix material causes scattering of the electromagnetic radiation in the outcoupling element.

30. The method according to claim 29, wherein the separated phase in the matrix material of the outcoupling element is produced by thermal treatment, by treatment with electromagnetic radiation and/or by addition of an initiator material.

31. The method according to claim 29, wherein applying the outcoupling element comprises mixing a blowing agent into the matrix material;
wherein the blowing agent, after application of the outcoupling element, is decomposed thermally and/or by radiation and forms a first compound that differs from the matrix material;
wherein the first compound forms a separated phase in the matrix material; and
wherein the blowing agent comprises an agent selected from the group consisting of hydrogencarbonate of the alkali metals, hydrogencarbonate of the alkaline earth metals, sodium hydrogencarbonate (NaHCO₃) and ammonium hydrogencarbonate (NH₄HCO₃).

32. The method according to claim 29, further comprising crosslinking of the matrix material after applying the outcoupling element and producing the layer structure.

33. The method according to claim 29, wherein a first compound that forms the separated phase is produced before or after producing the layer structure.

34. The method according to claim 29, wherein terminal groups in the matrix material decompose chemically and/or terminal groups in the matrix material react with other terminal groups in the matrix material and form at least one separated phase.

35. An optoelectronic component comprising:
an organic functional layer having an active region that emits electromagnetic radiation; and
an outcoupling element disposed in a beam path of the electromagnetic radiation emitted by the active region;
wherein the outcoupling element comprises a matrix material and a separated phase disposed therein or a multitude of separated phases different than the matrix material;
wherein a refractive index of the separated phase is less than a refractive index of the matrix material;
wherein the separated phase in the matrix material causes scattering of the electromagnetic radiation in the outcoupling element;
wherein the matrix material comprises a block copolymer, wherein the block copolymer comprises a first block having a thermally labile group of a first monomer unit from which a separated phase can be generated in the matrix material, and wherein the block copolymer comprises a second block, wherein the second block has a reactive crosslinkable group of a second monomer unit; and
wherein a refractive index of the outcoupling element is greater than or equal to 1.65.
